(19) United States
(12) Patent Application Publication
(10) Pub. No.: US 2008/0160755 A1
(43) Pub. Date: Jul. 3, 2008

(54) Method of Forming Interconnection of Semiconductor Device

(76) Inventor: SUNG JOONG JOO, Seo-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/929,920

(22) Filed: Oct. 30, 2007

(30) Foreign Application Priority Data
Dec. 28, 2006 (KR) 10-2006-0135794

(51) Int. Cl. H01L 21/4763

(52) U.S. Cl. 438/627; 257/E21.495

(57) ABSTRACT

Disclosed is a method of forming an interconnection of a semiconductor device. The method includes forming a lower interlayer insulating layer including a lower metal interconnection on a semiconductor substrate, forming an insulating layer and an upper interlayer insulating layer on the lower interlayer insulating layer, forming a damascene pattern of a contact hole or of a trench and a contact hole in the upper interlayer insulating layer, removing the insulating layer on the lower metal interconnection and in the same chamber forming a barrier metal layer on the damascene pattern having no insulating layer, removing the barrier metal layer on the lower metal interconnection, filling the damascene pattern with metal, and forming a metal interconnection by polishing the damascene pattern.

### CROSS-REFERENCE TO RELATED APPLICATION

The present application claims the benefit under 35 U.S.C. § 119 of Korean Patent Application No. 10-2006-0135794, filed Dec. 28, 2006, which is hereby incorporated by reference in its entirety.

### BACKGROUND

Recently, as semiconductor devices have become highly integrated and operated at a high speed, the size of a transistor has become gradually reduced. As the integration degree of a transistor increases, an interconnection of a semiconductor device is fabricated in a micro size. As a result, signals applied to the interconnection are delayed or distorted and thus the high-speed operation of the semiconductor device is interrupted.

In order to address such a problem, a copper interconnection using copper has been rapidly developed because the copper interconnection has a lower resistance and higher electro-migration as compared to aluminum or aluminum alloy that has been widely used as interconnection material of a semiconductor device. In order to form the copper interconnection, a copper layer is formed and then must be etched. However, copper has poor etching properties and the surface of the copper interconnection may become oxidized during the etching process.

Accordingly, a damascene process has been developed in order to address such a problem when forming the copper interconnection. According to a damascene process, a trench and a contact hole are formed in an insulating layer, a copper layer is deposited on the insulating layer such that the trench and contact hole are filled with the copper layer, and the copper layer is planarized through a Chemical Mechanical Polishing (CMP) process, so that the copper interconnection is formed in the trench and contact hole.

FIG. 1 is a sectional view showing a process of forming contact holes through a related metal interconnection formation process, i.e. a damascene or a dual damascene process. Referring to FIG. 1, a semiconductor substrate (not shown) including various elements for forming a semiconductor device is provided. For example, a transistor or a memory cell can be formed on the semiconductor substrate.

Then, a lower interlayer insulating layer 1 is formed on the semiconductor substrate, and a dual damascene pattern including a contact hole and a trench is formed on the lower interlayer insulating layer 1 through the dual damascene process. Next, the dual damascene pattern is filled with conductive material to form a lower metal interconnection 2. The lower metal interconnection 2 may include copper.

In order to prevent the metal component of the lower metal interconnection 2 from being diffused into the lower interlayer insulating layer 1, a barrier metal layer (not shown) may also be formed between the lower metal interconnection 2 and the lower interlayer insulating layer 1. An insulating layer 3, e.g. a nitride layer SiN, is formed on the lower interlayer insulating layer 1 including the lower metal interconnection 2, an upper interlayer insulating layer 4 is formed on the insulating layer 3, and a dual damascene pattern 5 is formed through the dual damascene process.

In the process of forming the dual damascene pattern 5 in the upper interlayer insulating layer 4, the insulating layer 3 is etched, so that the lower metal interconnection 2, e.g. copper, is exposed to atmosphere.

As a predetermined delay time passes, an oxide layer forms on the lower metal interconnection 2 exposed to atmosphere, so contact resistance is greatly increased. Accordingly, the delay time before the subsequent process is adjusted to reduce or prevent the oxide layer from being formed. Since the semiconductor process is a mass-production process, a predetermined delay time is required in order to perform the subsequent process after a predetermined process has been performed. This will be referred to as delay time in this application.

In order to inhibit the diffusion of the metal, e.g. copper, a barrier metal layer is formed after forming the dual damascene pattern. Before forming the barrier metal layer, a cleaning process is necessary for cleaning contaminant caused by the delay time. That is, according to the related metal interconnection formation process as described above, the insulating layer is etched in the process of forming the dual damascene pattern, so that the lower metal interconnection is exposed to atmosphere. Therefore, the delay time adjustment and additional cleaning process are necessary.

### BRIEF SUMMARY

Embodiments of the present invention provide a method of forming an interconnection of a semiconductor device.

In an embodiment of the present invention, there is provided a method of forming an interconnection of a semiconductor device, in which delay time adjustment and additional cleaning process are not necessary, and contact resistance can be stably ensured.

In one embodiment of the present invention, there is provided a method of forming an interconnection of a semiconductor device comprising: forming a lower interlayer insulating layer including a lower metal interconnection on a semiconductor substrate; forming an insulating layer and an upper interlayer insulating layer on the lower interlayer insulating layer; forming a damascene pattern of a contact hole or of a trench and a contact hole in the upper interlayer insulating layer; removing the insulating layer on the lower metal interconnection; forming a barrier metal layer on the damascene pattern having no insulating layer; removing the barrier metal layer on the lower metal interconnection; filling the damascene pattern with metal; and forming a metal interconnection by polishing the metal filled damascene pattern.

In another embodiment of the present invention, there is provided a method of forming an interconnection of a semiconductor device comprising: forming a damascene pattern in an upper interlayer insulating layer such that a lower conductive interconnection in a lower interlayer insulating layer is blocked from exposure by an insulating layer on the lower conductive interconnection; and forming a barrier metal layer by partially removing the insulating layer being in contact with the lower conductive interconnection.

The details of one or more embodiments are set forth in the accompanying drawings and the description below. Other features will be apparent from the description and drawings, and from the claims.

### BRIEF DESCRIPTION OF THE DRAWINGS

FIG. 1 is a cross-sectional view for explaining a process of forming contact holes through a related metal interconnection formation process.

FIGS. 2-6 are cross-sectional views showing a procedure of forming a metal interconnection according to an embodiment of the present invention.

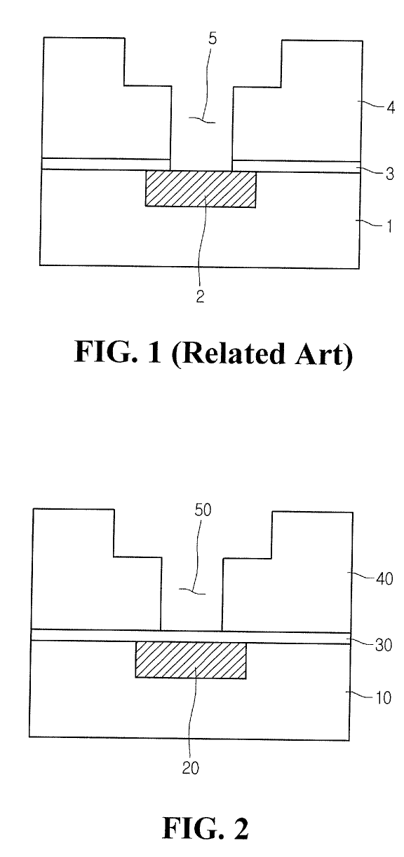

### DETAILED DESCRIPTION

Hereinafter, embodiments will be described in detail with reference to the accompanying drawings. First, it should be noted that identical elements or parts have been designated by the same reference numbers in the drawings. In the description of the embodiment, the detailed description of related known functions or constructions will be omitted herein to avoid making the subject matter of the embodiment ambiguous.

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present. Thus, the meaning thereof can be determined based on the scope of the embodiment.

FIGS. 2 through 6 are cross-sectional views showing a procedure of forming a metal interconnection according to an embodiment. First, a semiconductor substrate (not shown) including various elements of a semiconductor device is provided. For example, a transistor or a memory cell (not shown) can be formed on the semiconductor substrate.

Referring to FIG. 2, a lower interlayer insulating layer 10 can be formed on the semiconductor substrate, and a lower metal interconnection 20 can be formed. The lower metal interconnection 20 may include copper. In order to inhibit the metal component of the lower metal interconnection 20 from being diffused into the lower interlayer insulating layer 10, a barrier metal layer (not shown) may also be formed between the lower metal interconnection 20 and the lower interlayer insulating layer 10.

An insulating layer 30 can be formed on the lower interlayer insulating layer 10 including the lower metal interconnection 20. The insulating layer 30 can be a silicon nitride layer. In one embodiment, the insulating layer 30 can have a thickness between about 200 Å and about 600 Å. An upper interlayer insulating layer 40 can be formed on the insulating layer 30, and a dual damascene pattern 50 can be formed through a dual damascene process.

In the process of forming the dual damascene pattern 50 in the upper interlayer insulating layer 40, the insulating layer 30 is not etched. That is, in the process of forming the dual damascene pattern 50, since RIE (reactive ion etching) and wet etching processes are not performed, the insulating layer 30 is not etched, so the lower metal interconnection 20 under the insulating layer 30 is not exposed to atmosphere.

The upper interlayer insulating layer 40 can include a FSG (Fluorine doped Silicate Glass) or USG (Undoped Silicate Glass) of low-k material. After forming the dual damascene pattern 50 in the upper interlayer insulating layer 40, the resultant structure is shifted to a barrier metal chamber. The barrier metal chamber, for example, may include a chamber for TaN deposition.

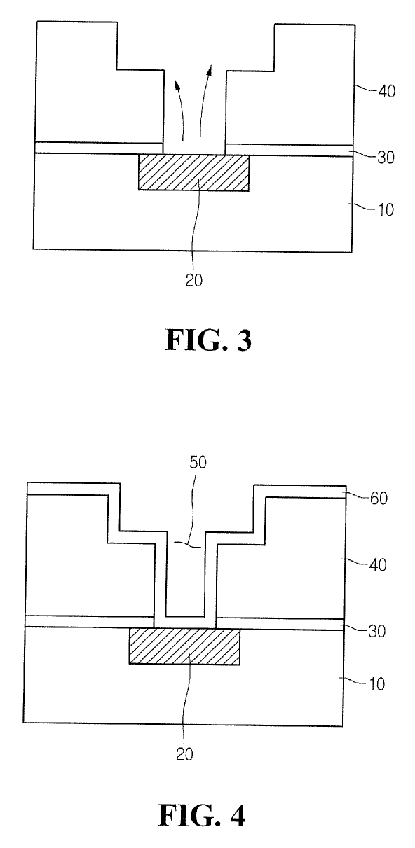

Referring to FIG. 3, the insulating layer 30 on the lower metal interconnection 20 can be removed in the chamber. The insulating layer 30 can be removed using a resputtering method that applies DC power and RF bias to the semiconductor substrate in the atmosphere of Ar gas.

The resputtering method performs sputtering by using a Ta coil additionally installed in the sputtering chamber. The sputtering is performed in two steps. In the first step, power of 300 W to 600 W is applied to a lower bias. In the second step, power of 900 W to 1200 W is applied to the lower bias. In the first and second steps, Ar sputtering is performed for 10 seconds to 30 seconds while constantly maintaining pressure of 3000 mTorr to 4000 mTorr. In a specific embodiment, power of 200 W to 300 W is applied to the Ta coil.

As the resputtering is performed under the conditions as described above, the insulating layer 30 on the bottom surface of the contact hole of the dual damascene pattern 50 is removed, and Ta is redeposited in the trench. Further, Ta generated from the coil compensates for Ta lost due to the resputtering.

Referring to FIG. 4, TaN and Ta can be sequentially redeposited on the resultant structure to form a barrier metal layer 60. The TaN or the Ta can have a thickness of between about 50 Å and about 100 Å.

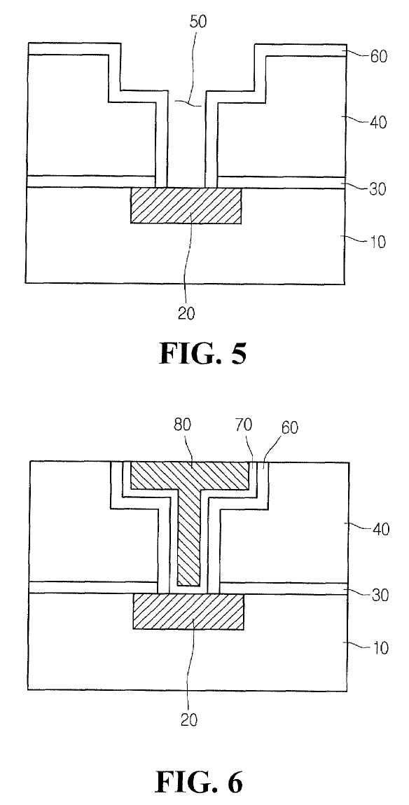

Referring to FIG. 5, the Ta resputtering process can be performed to remove the barrier metal layer on the bottom surface of the contact hole of the dual damascene pattern 50, thereby exposing the lower metal interconnection 20. The Ta resputtering process can be performed under the conditions in which power of 250 W to 350 W is applied to the Ta coil and power of 350 W to 450 W is applied to the lower bias.

Then, the lower metal interconnection 20 is exposed, and metal is filled on the entire surface of the dual damascene pattern 50 including the lower metal interconnection 20. A CMP (chemical mechanical polishing) process can be performed with respect to the metal to form a metal interconnection. The following description discloses a process of forming a seed-Cu layer to deposit copper, when the metal interconnection includes copper.

Referring to FIG. 6, a seed-Cu layer 70 having a thickness between about 400 Å and about 800 Å can be deposited on the exposed lower metal interconnection 20 and damascene pattern 50. Then, copper can be electroplated on the seed-Cu layer 70 through electroplating to fill the dual damascene pattern 50 with the copper. Then the dual damascene pattern 50 can be polished through the CMP process to form a copper interconnection 80.

Although the embodiment has been described in relation to the dual damascene process, embodiments are also applicable for a single damascene process.

According to embodiments of the present invention, the insulating layer on the lower metal interconnection is not removed in the process of forming the damascene pattern through the damascene process. The insulating layer is removed before forming the barrier metal layer in the barrier metal chamber, so that the delay time adjustment and additional cleaning process are not necessary and the contact resistance can be stably ensured.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of forming an interconnection of a semiconductor device, comprising:
forming a lower interlayer insulating layer including a lower metal interconnection on a semiconductor substrate;
forming an insulating layer and an upper interlayer insulating layer on the lower interlayer insulating layer;
forming a damascene pattern in the upper interlayer insulating layer;
removing the insulating layer on the lower metal interconnection;
forming a barrier metal layer on the damascene pattern having no insulating layer;
removing the barrier metal layer on the lower metal interconnection; and
filling the damascene pattern with metal.

2. The method according to claim 1, wherein the insulating layer comprises SiN.

3. The method according to claim 1, wherein the insulating layer has a thickness between about 200 Å and about 600 Å.

4. The method according to claim 1, wherein the upper interlayer insulating layer comprises Fluorine doped Silicate Glass (FSG) or Undoped Silicate Glass (USG).

5. The method according to claim 1, wherein removing the insulating layer on the lower metal interconnection comprises performing a resputtering process in a barrier metal chamber.

6. The method according to claim 5, wherein the barrier metal chamber comprises a TaN chamber.

7. The method according to claim 5, wherein the resputtering process is performed through a first step of applying power of 300 W to 600 W to a lower bias in an atmosphere of Ar gas, and a second step of applying power of 900 W to 1200 W to the lower bias in an atmosphere of Ar gas.

8. The method according to claim 7, wherein the first step and the second step of the resputtering process is performed for 10 seconds to 30 seconds while constantly maintaining pressure of 3000 mTorr to 4000 mTorr.

9. The method according to claim 1, wherein removing the barrier metal layer comprises performing a Ta resputtering process in which power of 250 W to 350 W is applied to a Ta coil and power of 350 W to 450 W is applied to a lower bias.

10. The method according to claim 1, wherein the metal comprises copper.

11. A method of forming an interconnection of a semiconductor device, comprising:
forming a damascene pattern in an upper interlayer insulating layer such that a lower conductive interconnection is blocked from exposure by an insulating layer on the lower conductive interconnection; and
forming a barrier metal layer by partially removing the insulating layer being in contact with the lower conductive interconnection.

12. The method according to claim 11, further comprising forming an upper conductive interconnection by filling the damascene pattern having the barrier metal layer with metal.

13. The method according to claim 12, wherein the upper conductive interconnection comprises copper.

14. The method according to claim 11, wherein removing the insulating layer comprises performing a resputtering process in a barrier metal chamber.

15. The method according to claim 14, wherein performing the resputtering process redeposits barrier metal layer material in the damascene pattern.

16. The method according to claim 15, wherein the barrier metal layer material comprises tantalum (Ta).

17. The method according to claim 14, wherein forming the barrier metal layer further comprises redepositing barrier metal layer material on the damascene pattern.

18. The method according to claim 11, wherein forming the damascene pattern comprises performing a dual damascene process or a single damascene process.

19. The method according to claim 11, wherein the lower conductive interconnection is blocked from exposure by the insulating layer on the lower conductive interconnection, so that the lower conductive interconnection is not exposed to atmosphere.
